(19) United States
(12) Patent Application Publication
(10) Pub. No.: US 2007/0278471 A1
(43) Pub. Date: Dec. 6, 2007

(54) Novel chalcogenide material, switching device and array of non-volatile memory cells

(76) Inventors: Bomy Chen, Cupertino, CA (US); Yin Yin Lin, Shanghai (CN)

Correspondence Address: DLA PIPER US LLP, 2000 UNIVERSITY AVENUE, E. PALO ALTO, CA, 94303-2248, US

(21) Appl. No.: 11/443,876

(22) Filed: May 30, 2006

(51) Int. Cl. H01L 29/06

(52) U.S. Cl. 257/5; 438/95; 365/163

(57) ABSTRACT

A novel chalcogenide material has a bulk composition which has a first material selected from the group of Si and Sn, a second material selected from the group of Sb, and a third material selected from the group of Te. The first material, second material, and third material are in a ratio of (Siₓ or Sn_{y}) Sb₂ Te₅, where x is 1≦x≦5, and y is 0.5≦y≦2.0. The material can be used in a switch device, which includes a dielectric/heater layer having a first surface and a second surface opposite the first surface, and the material having a first surface and a second surface opposite the first surface; with the first surface of the material immediately adjacent to and in contact with the first surface of the dielectric/heater layer. A first electrical contact is on the second surface of the dielectric/heater layer. A second electrical contact is on the second surface of the phase changing chalcogenide material. A third electrical contact is on the second surface of the phase changing chalcogenide material, spaced apart from the second electrical contact. The switching device can be programmed such that the channel length separation between the second electrical contact and the third electrical contact on the phase changing chalcogenide material is changed to represent the desired state to be stored in the device. Finally, an array of the above described non-volatile memory cells can be formed in a dielectric/heater layer and the chalcogenide material.

### TECHNICAL FIELD

The present invention relates to a novel chalcogenide material that can be used in a switching device and with a plurality of switching devices arranged as an array of non-volatile memory cells.

### BACKGROUND OF THE INVENTION

Chalcogenide material such as Ge₂Sb₂Te₅ are well known in the art. Typically, chalcogenide materials have the property that the phase of the material changes depending upon the amount of current passing there through. This change in the phase of the material affects certain properties such as optical properties as well as electrical properties. Thus, chalcogenide material with changing optical properties have been used in the read/write CD industry to produce a read/write CD-ROM. Chalcogenide materials have also been suggested for use as a non-volatile diode in an array for storage of a desired state.

Chalcogenide material such as Ge₂Sb₂Te₅ have also been doped, similar to the doping of semiconductor materials, to improve the electrical properties. By suitably doping the chalcogenide material, the ratio of the resistance on to the resistance off can be altered. As is well known in the art, a high Rₒₙ/R_{off} ratio is desirable. However, thus far, the chalcogenide material Ge₂Sb₂Te₅ has achieved an electrical characteristics of no better than Rₒₙ/R_{off} of 1E5.

Finally, chalcogenide material has been proposed to be used as a switching device. See, for example, U.S. Publication 2004/0178404 published Sep. 16, 2004 as well as Publication 2004/0178403 published Sep. 16, 2004.

Accordingly, it is one object of the present invention to show a novel chalcogenide material having increased Rₒₙ/R_{off} ratio thereby making it more suitable as an electrical device. Further, the material can be used in a switching device and with a plurality of the devices arranged in an array as an array of non-volatile memory cells.

### SUMMARY OF THE INVENTION

Accordingly, in the present invention, a novel chalcogenide material comprises a bulk composition consisting of a first material selected from the group of Si and Sn; a second material selected from the group of Sb; and a third material selected from the group of Te. The first material, second material, and third material are in a ratio of (Siₓ or Sn_{y}) Sb₂ Te₅ where x is 1≦x≦5; and y is 0.5≦y≦2.0.

The present invention also relates to a non-volatile memory device comprising a dielectric/heater layer having a first surface and a second surface opposite the first surface, and the aforementioned novel chalcogenide material. The chalcogenide material has a first surface and a second surface opposite the first surface with the first surface immediately adjacent to and in contact with the first surface of the dielectric/heater layer. A first electrical contact is on the second surface of the dielectric/heater layer. A second electrical contact is on the second surface of the phase changing chalcogenide material. A third electrical contact is on the second surface of the phase changing chalcogenide material, spaced apart from the second electrical contact.

Finally, the present invention relates to an array of aforementioned non-volatile memory devices. The array of non-volatile memory devices is arranged in a common dielectric layer and the above described phase changing chalcogenide material. The plurality of memory cells are arranged in a plurality of rows and columns, with each memory cell having a first electrical contact and a second electrical contact on the surface of the phase changing chalcogenide material; and a third electrical contact on the surface of the dielectric/heater layer. The memory cells in the same row have their third electrical contacts electrically connected and are substantially co-linear. The memory cells in the same column have their first electrical contacts electrically connected and are substantially co-linear and the second electrical contacts electrically connected and are substantially co-linear. The memory cells in adjacent columns share a common first electrical contact to one side; and share a common second electrical contact to another side.

### BRIEF DESCRIPTION OF THE DRAWINGS

FIGS. 1(a-d) are cross-sectional views of a non-volatile memory device using the novel phase changing material of the present invention. The cross sectional views show the various possible states that can be stored in a single non-volatile memory device, wherein the state stored is a function of the channel length.

FIG. 2 is a top view of an array of non-volatile memory cells of the present invention, showing the sharing of common source/drain lines.

FIG. 3 is a cross-sectional view of a non-volatile memory cell of the present invention showing the bi-directional read capability of such a cell.

FIG. 4 is a graph showing the operation of the cell shown in FIG. 4, showing the difference in the read current as a function of the direction of read.

FIG. 5 is a cross sectional view showing an array of non-volatile memory cells of the present invention stacked with and electrically connected to a conventional silicon semiconductor substrate, with its integrated circuits.

### DETAILED DESCRIPTION OF THE INVENTION

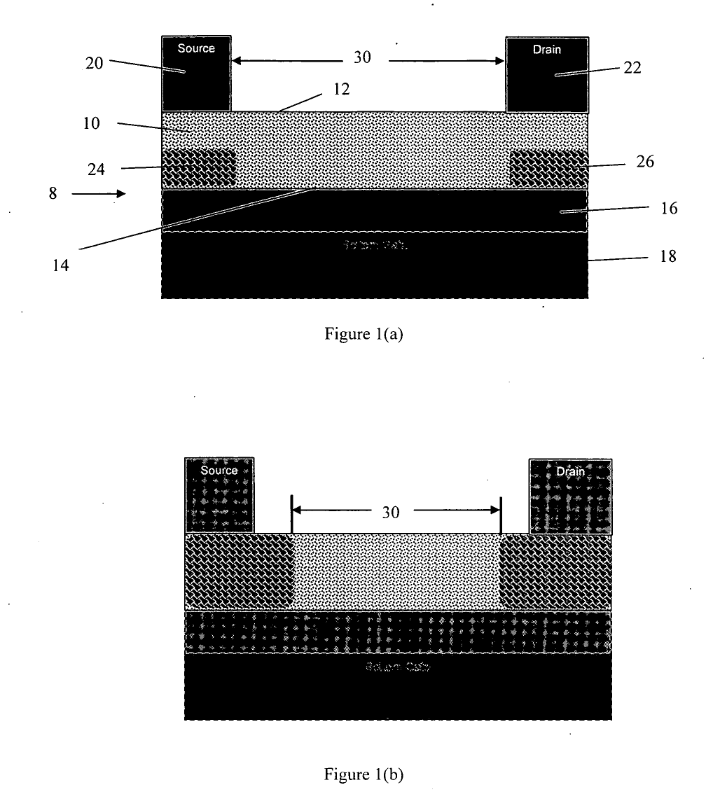

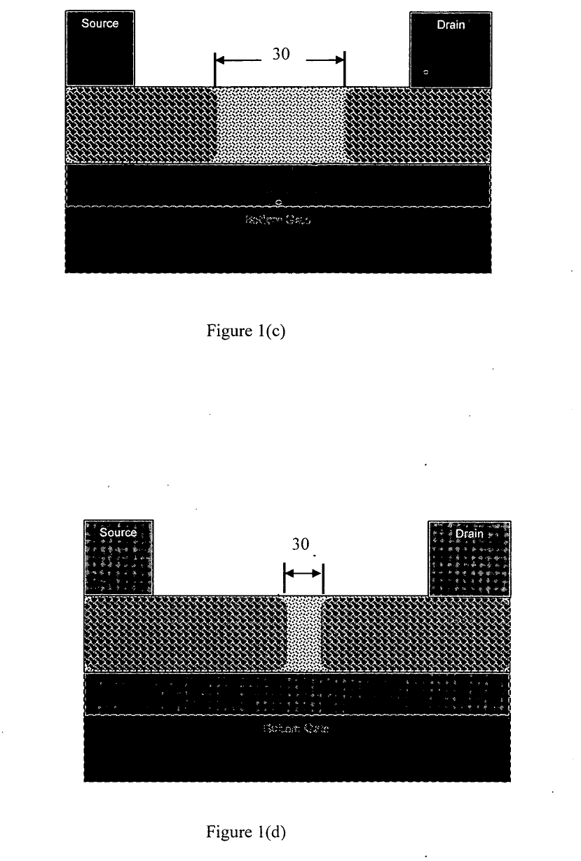

Referring to FIG. 1A, there is showing a cross-sectional view of a novel non-volatile memory cell 8 of the present invention using a novel chalcogenide material 10. The novel chalcogenide material 10 which is a phase changing material has a bulk composition which consists of a first material selected from the group consisting of Si and Sn, a second material selected from the group Sb, and a third material from the group of Te. The first material, second material and third material are in a ratio of (Siₓ or Sn_{y})Sb₂Te₅ where x is between 1 and 5 and y is between 0.5 and 2.0. The chalcogenide material 10 has a bulk composition consisting of the foregoing three materials in that the three materials form the bulk of the chalcogenide material 10. As is well known from semiconductor processing, dopants can also be added to the bulk composition to alter the electrical characteristics of the bulk composition. In particular, doping material such as boron, aluminum, phosphorus and arsenic may be implanted or otherwise deposited into the chalcogenide material 10 to alter its electrical composition.

One particular example of the bulk composition is Siₓ Sb₂ Te₅ where 1≦x≦5. In such an example, it has been found that such a bulk composition has an electrical characteristics of Rₒₙ/R_{off} to be greater than 1E6. Another example of the bulk composition consists of Sn_{y}Sb₂Te₅ where y is on the order of 1E4. In such a composition, the use of Sn in lieu of the prior art Ge causes the bulk composition to have a phase transition faster then 0.01 microsecond.

Thus, as can be seen from the foregoing, by using either Si or Sn in lieu of the prior art Ge, the electrical characteristics of the chalcogenide material 10 can be improved or where desired, the speed of the phase transition can be improved.

Referring back to FIG. 1A again, the novel non-volatile memory cell 8 of the present invention comprises the novel phase changing chalcogenide material 10 having the aforementioned described bulk composition. The material 10 has a first surface 12 and a second surface 14 which is substantially opposite thereto. The material 10 is a layer material on the order of 100-3,000 angstroms in thickness, in the preferred embodiment and is deposited on a layer of a dielectric/heater material 16. The dielectric/heater material 16 also has a first surface and a second surface opposite the first surface. The second surface of the dielectric/heater layer 16 is immediately adjacent to and is in contact with the second surface 14 of the chalcogenide material 10. In the preferred embodiment, the dielectric/heater layer 16 is a material (e.g. SiO₂ or Si₃N₄ or Al₂O₃, etc.).

A first electrical contact 18 is formed on the first surface of the dielectric/heater layer 16. A second electrical contact 20, labeled a source, which is familiar to those of semiconductor processing art, is in contact with the first surface 12 of the chalcogenide material 10. Spaced apart from the source 20 is a third electrical contact 22, labeled drain. The drain is also in contact with the first surface 12 of the chalcogenide material 10.

In the operation of the memory cell 8, a current is supplied between either the source 20 and the first contact 18 or between the drain 22 and the first contact 18. Thus, for example, if a current is supplied between the source 20 and the first contact 18, the current changes a portion 24 of the chalcogenide material 10 so that its phase is changed. As can be seen in FIG. 1A, a first portion 24 of the chalcogenide material 10 has changed its phase. In so changing its phase, the first portion 24 has also changed its electrical characteristics becoming more electrically conductive. Similarly, when a current is supplied between the drain 22 and the first contact 18, the phase of a second portion 26 of the chalcogenide material 10 is changed. Again, this changing of the phase of the chalcogenide material in the second portion 26 has rendered it more electrically conductive. Between the first portion 24 and the second portion 26 is the unchanged chalcogenide material 30 which is electrically equivalent to a channel of a FET transistor. Depending upon the amount of the first portion 24 and the second portion 26 which has been changed, the length or the distance of the channel region 30 between the first portion 24 and the second portion 26 can be changed. Thus, as can be seen in FIG. 1A, if the current between the source 20 and the first contact 18 and between the drain 22 and the first contact 18 is of a minimal period, the least amount of chalcogenide material 10 has been changed to the first portion 24, the second portion 26, respectively.

In contrast, in FIG. 1B, there is shown a greater portion of the first portion 24 and the second portion 26 of the chalcogenide material 10 having the phase changed. In so changing the greater portion of the first portion 24 and the second portion 26, this has reduced the channel length 30 between the first portion 24 and the second portion 26.

Referring to FIG. 1C, there is shown a third possibility of the amount of time in changing the first portion 24 and the second portion 26. In this embodiment shown in FIG. 1C, the current has been sustained longer then the embodiment shown in FIG. 1A and FIG. 1B. Thus, the channel length 30 is even shorter in the embodiment shown in FIG. 1C, than the embodiment shown in FIG. 1B or 1A.

Finally, in FIG. 1D there is shown the narrowest or the shortest channel length 30 between the first portion 24 and the second portion 26.

The change in the channel length 30 between the first portion 24 and the second portion 26 can be used to store a desired state. Therefore, as can be seen in FIGS. 1A-1D, a multilevel cell for storing a plurality of bits with each bit having two states, can be stored in a single non-volatile memory cell 8. By changing the channel length 30 from the embodiment shown in FIG. 1A-1D, the electrical characteristics of the embodiment shown in FIG. 1A-1D would differ. This result is then detectable during a read operation causing the cell 8 to distinguish the various states that had been stored therein.

During the read operation, a voltage is applied to the first contact 18. The first contact 18 serves similar to the “gate” of an FET transistor. A first voltage and a second voltage are applied to the source 20 and the drain 22, respectively. The amount of current flowing between the source 20 and the drain 22 would depend upon the length of the channel region 30 which in turn would depend upon the state that is stored in the cell 8.

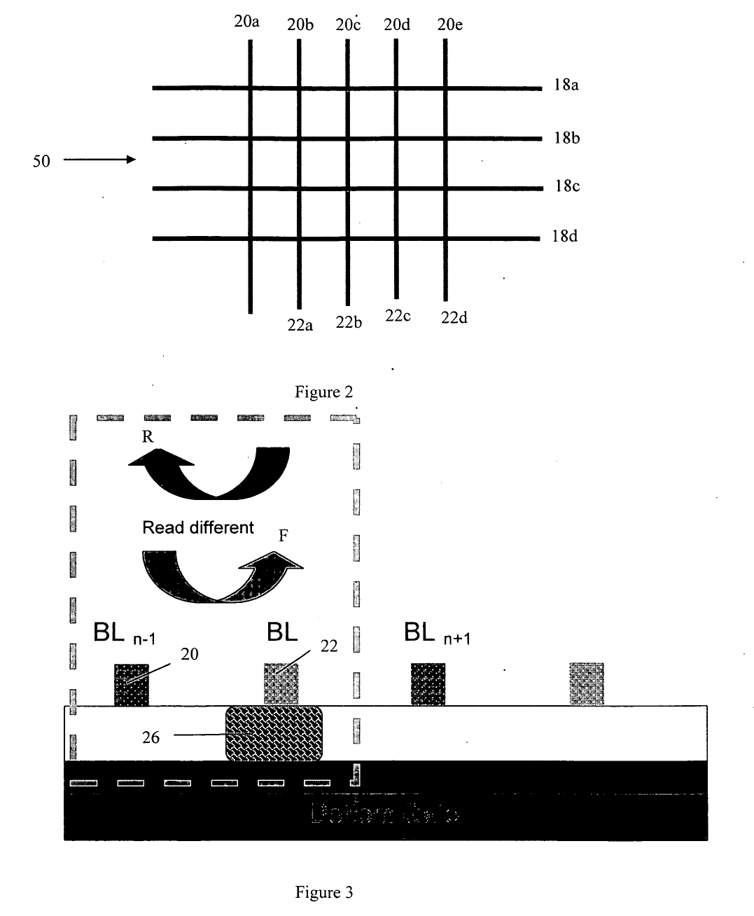

Referring to FIG. 2 there is shown a top view of an array 50 of the non-volatile memory cells 8 of the present invention. The array 50 comprises a plurality of memory cells 8 arranged in a plurality of rows and columns. As is well known to those skilled in the art, the term “row” and “column” can be used interchangeably. In essence, rows and columns are substantially perpendicular to one another. The array 50 comprises a layer of the dielectric/heater layer 16 having a first surface and a second surface as described heretofore. The array 50 further comprises a layer of chalcogenide material 10 having a first surface 12 and a second surface 14 in contact with the second surface of the dielectric/heater layer 16. A plurality of spaced apart row lines 18 (a-d), spaced apart from one another, are shown in contact with the first surface of the dielectric/heater layer 16. Finally, a plurality of column lines 20 (a-e) are spaced apart from one another and are in contact with and immediately adjacent to the first surface 12 of the chalcogenide material 10. Further, each column line serves as a source line 20 to the cells 8 on one side and serves as a drain line 22 to the cells 8 on the adjacent side. Thus, for example, the column line 22a is the drain line to the source line 20a but is also the source line 20b. Therefore, memory cells 8 in immediate adjacent columns share the same source line 20 to one side and share the same drain line 22 on another side.

The operation for programming each of the non-volatile memory cells 8 is as described heretofore. For example, if it is desired to program the cell 8 defined by the intersection of the source line 20a and drain line 22a and the row line 18a, then a current is applied between the source line 20a and row line 18a. Another current may also be applied between the drain line 22a and the row line 18a. This then forms the first and second portions for 24 and 26 within the chalcogenide material 10, respectively, all as described heretofore. A reading of that cell 8 would occur by applying a voltage to the row on 18a and applying a first and second voltages to the source 20a and drain 22a, respectively, and measuring the current flow there through.

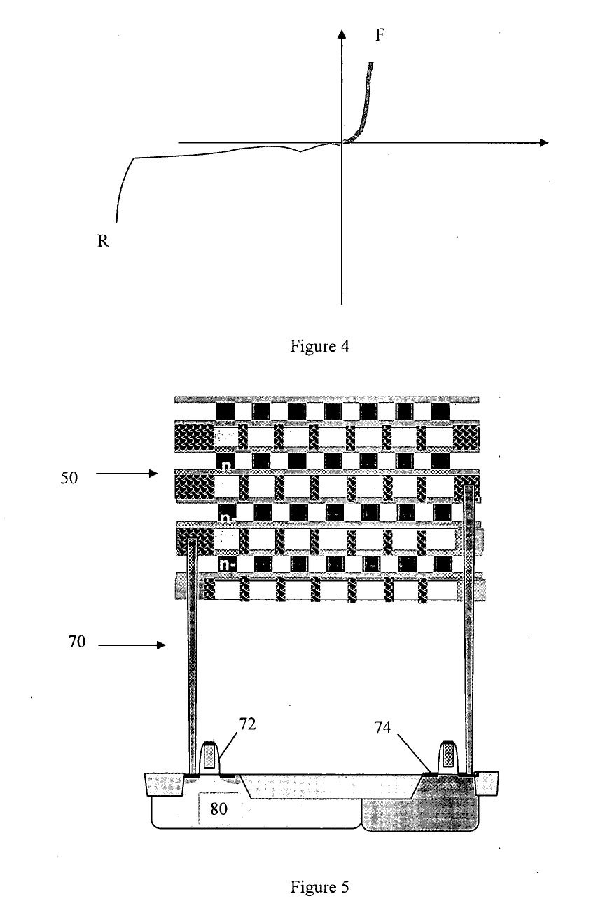

Referring to FIG. 3 there is shown another novel aspect of the memory cell 8 and the array 50 of the present invention. The memory cell 8 or a memory cell 8 within an array 50 can be read bi-directionally. Referring to FIG. 3 there is shown a cross-sectional view of a non-volatile memory cell 8 in which only a second portion 26 of the chalcogenide material 10 is formed. Using the novel chalcogenide material 10, it has been found that passing a read current from the source 20 to the drain 22 in two different directions causes two different currents to be read. For example, if a current were supplied from the source 20 to the drain 22, the forward current is shown in FIG. 4. On the other hand, if the same voltages were reversed and a current were supplied from the drain 22 to the source 20, the reverse current would result shown in FIG. 4. Thus, the operation of the device 8 shown in FIG. 3 operates similar to a diode in that electrical characteristics would differ depending on the direction of the current flow. In this manner, because the direction of the current read can be changed to detect different states, a novel non-volatile memory cell 8 with a bi-directional read capability is shown.

Referring to FIG. 5 there is shown a cross-sectional view of an integrated circuit device 70 incorporating an array 50 of the novel non-volatile memory cells 8 of the present invention. In the device 70 shown in FIG. 5, conventional FET transistors 72 and 74 are shown made in a silicon semiconductor substrate 80. As is well known in the art of semiconductor processing, the area in a semiconductor substrate 80 is limited. As more circuits are made in the substrate 80, it becomes increasingly difficult to create integrated circuit devices 70 having small footprint or small area. Small footprint or small die size is desirable in order to minimize cost and increase yield. Because the non-volatile memory cells 8 and the array 50 are made out of a chalcogenide material, they can be formed in a step apart from the formation of the silicon substrate 80 based integrated circuits. Further, the device 50 can even be a plurality of layers of arrays 50 interconnected and stacked on one another, as shown in FIG. 5. Once the array or arrays 50 are formed, the entire array 50 can then be electrically comected to the semiconductor substrate 80 which may have logic circuits and drivers and sense amplifiers and the like. In this manner, the integrated circuit device 70 can be made much more compact. Further, the entire array 50 of the non-volatile memory cells 8 can be made in a post-substrate 80 processing process, known as the back end process. Thus, it is possible to make the arrays 50 separately and then electrically connecting to the substrate 80 which has been processed by the conventional silicon processing method.

From the foregoing, it can be seen that a novel chalcogenide material 10 has been discovered and a non-volatile memory cell 8 with switching properties and non-volatile retention properties is shown. Further, an array 50 of such non-volatile memory cells 8 can be efficiently and economically formed which then can be electrically connected to a conventional semiconductor substrate 80 with logic circuits and the like formed on the substrate 80.

What is claimed is:

1. A phase changing chalcogenide material comprising:
a bulk composition consisting of:
a first material selected from the group of Si and Sn;
a second material selected from the group of Sb;
a third material selected from the group of Te;
wherein said first material, second material, and third material are in a ratio of (Siₓ or Sn_{y}) Sb₂ Te₅
where x is 1≦x≦5, and
y is 0.5≦y≦2.0

2. The material of claim 1 wherein said bulk composition consists of:
Siₓ Sb₂ Te₅, where 1≦x≦5, wherein said composition having an electrical characteristics of at least Rₒₙ/R_{off}=1E6.

3. The material of claim 1, wherein said bulk composition consists of Sn_{y} Sb₂ Te₅, where y is on the order of 1E4, and wherein said composition having a phase transition faster then 0.01 microsecond.

4. The material of claim 2 further comprising a dopant doped into said bulk composition.

5. The material of claim 4 wherein said dopant is a material selected from the group consisting of Boron, Aluminum, Phosphorus, and Arsenic.

6. A non-volatile memory device comprising:
a dielectric/heater layer having a first surface and a second surface opposite said first surface;
a phase changing chalcogenide material having a bulk composition consisting of:
a first material selected from the group of Si and Sn;
a second material selected from the group of Sb;
a third material selected from the group of Te;
wherein said first material, second material, and third material are in a ratio of (Siₓ or Sn_{y}) Sb₂ Te₅
where x is 1≦x≦5;
y is 0.5≦y≦2.0
said phase changing chalcogenide material having a first surface and a second surface opposite said first surface; said first surface immediately adjacent to and in contact with the first surface of the dielectric/heater layer;
a first electrical contact on the second surface of the dielectric/heater layer;
a second electrical contact on the second surface of the phase changing chalcogenide material; and
a third electrical contact on the second surface of the phase changing chalcogenide material, spaced apart from the second electrical contact.

7. The device of claim 6 wherein said bulk composition consists of:
Siₓ Sb₂ Te₅, where 1≦x≦5, wherein said composition having an electrical characteristics of at least Rₒₙ/R_{off}=1E6.

8. The device of claim 6, wherein said bulk composition consists of Sn_{y} Sb₂ Te₅, where y is on the order of 1E4, and wherein said composition having a phase transition faster then 0.01 microsecond.

9. The device of claim 7 further comprising a dopant doped into said bulk composition.

10. The device of claim 9 wherein said dopant is a material selected from the group consisting of Boron, Aluminum, Phosphorus, and Arsenic.

11. The device of claim 6 wherein said dielectric/heater layer consists of a chalcogenide material doped with nitrogen.

12. The device of claim 11 wherein said dielectric/heater layer consists of GST doped with at least ten percent (10%) nitrogen.

13. A method of programming a non-volatile memory device to a desired state, having a layer of a phase changing material having a first surface and a second surface substantially opposite said first surface, and a first electrical contact and a second electrical contact in contact with said material along said first surface, said first electrical contact being spaced apart from said second electrical contact, and defining a channel length therebetween, said method comprising:
applying a current between one of said first or second contact and said second surface; and
changing a portion of said material between said first surface and said second surface, thereby changing said channel length between said first electrical contact and said second electrical contact;
wherein said changed channel length reflects the desired state.

14. The method of claim 13 wherein said phase changing material comprises:
a bulk composition consisting of:
a first material selected from the group of Si and Sn;
a second material selected from the group of Sb;
a third material selected from the group of Te;
wherein said first material, second material, and third material are in a ratio of (Siₓ or Sn_{y}) Sb₂ Te₅
where x is 1≦x≦5; and
y is 0.5≦y≦2.0.

15. The method of claim 14 wherein said bulk composition consists of:
Siₓ Sb₂ Te₅, where 1≦x≦5, wherein said composition having an electrical characteristics of at least Rₒₙ/R_{off}=1E4.

16. The method of claim 14, wherein said bulk composition consists of Sn_{y} Sb₂ Te₅, where y is on the order of 1E4, and wherein said composition having a phase transition faster then 0.01 microsecond.

17. The method of claim 14 further comprising a dopant doped into said bulk composition.

18. The method of claim 17 wherein said dopant is a material selected from the group consisting of Boron, Aluminum, Phosphorus, and Arsenic.

19. The method of claim 13 wherein the number of desired states is greater than 2.

20. An array of non-volatile memory cells comprising:
a dielectric/heater layer having a first surface and a second surface opposite said first surface;
a phase changing chalcogenide material having a bulk composition consisting of:
a first material selected from the group of Si and Sn;
a second material selected from the group of Sb;
a third material selected from the group of Te;
wherein said first material, second material, and third material are in a ratio of (Siₓ or Sn_{y}) Sb₂ Te₅
where x is 1≦x≦5; and
y is 0.5≦y≦2.0
said phase changing chalcogenide material having a first surface and a second surface opposite said first surface; said first surface adjacent to the first surface of the dielectric/heater layer;
wherein said array comprises a plurality of memory cells arranged in a plurality of rows and columns, with each memory cell having a first electrical contact and a second electrical contact on the second surface of the phase changing chalcogenide material; and a third electrical contact on the second surface of the dielectric/heater layer;
wherein memory cells in the same row have their third electrical contacts electrically connected and are substantially co-linear;
wherein memory cells in the same column have their first electrical contacts electrically connected and are substantially co-linear and second electrical contacts electrically connected and are substantially co-linear; and
wherein memory cells in adjacent columns share a common first electrical contact to one side; and share a common second electrical contact to another side.

21. The array of claim 20 wherein said phase changing chalcogenide material comprises:
a bulk composition consisting of:
a first material selected from the group of Si and Sn;
a second material selected from the group of Sb;
a third material selected from the group of Te;
wherein said first material, second material, and third material are in a ratio of (Siₓ or Sn_{y}) Sb₂ Te₅
where x is 1≦x≦5; and
y is 0.5≦y≦2.0.

22. The array of claim 21 wherein said bulk composition consists of:
Siₓ Sb₂ Te₅, where 1≦x≦5, wherein said composition having an electrical characteristics of at least Rₒₙ/R_{off}=1E6.

23. The array of claim 21, wherein said bulk composition consists of Sn_{y} Sb₂ Te₅, where y is on the order of 1E4, and wherein said composition having a phase transition faster then 0.01 microsecond.

24. The array of claim 21 further comprising a dopant doped into said bulk composition.

25. The array of claim 24 wherein said dopant is a material selected from the group consisting of Boron, Aluminum, Phosphorus, and Arsenic.

26. The array of claim 20 wherein each cell can stored a number of states greater than 2.

27. The array of claim 20 wherein each cell is bi-directional.

28. The array of claim 20 further comprising an integrated circuit device on a semiconductor substrate, wherein said array and said semiconductor substrate are in a stacked, electrically connected relationship.
